(19) United States
(12) Patent Application Publication
(10) Pub. No.: US 2016/0018740 A1
(43) Pub. Date: Jan. 21, 2016

(54) EXPOSURE METHOD, EXPOSURE APPARATUS, AND METHOD FOR MANUFACTURING SEMICONDUCTOR DEVICE

(71) Applicant: KABUSHIKI KAISHA TOSHIBA, Tokyo (JP)

(72) Inventors: Takashi SATO, Fujisawa (JP); Ryoichi SUZUKI, Yokohama (JP); Shinichi ITO, Yokohama (JP)

(21) Appl. No.: 14/604,818

(22) Filed: Jan. 26, 2015

(30) Foreign Application Priority Data
Jul. 15, 2014 (JP) 2014-145142

(51) Int. Cl. G03F 7/20; H01L 21/027; H01L 21/268

(52) U.S. Cl. CPC G03F 7/70058; H01L 21/2686; H01L 21/0274; G03F 7/2022

(57) ABSTRACT

According to one embodiment, an exposure method is disclosed. The method includes irradiating a first light and a second light on a mask including a plurality of light transmitting portions arranged in a periodic pattern. The first light has a peak of intensity at a first wavelength. The second light has a peak of intensity at a second wavelength. The first wavelength is shorter than a distance between the mask and a substrate disposed to be separated from the mask. The second wavelength is longer than the first wavelength. The method includes irradiating a first interference light transmitted through the light transmitting portions and a second interference light transmitted through the light transmitting portions on the substrate.

### CROSS-REFERENCE TO RELATED APPLICATIONS

This application is based upon and claims the benefit of priority from Japanese Patent Application No. 2014-145142, filed on Jul. 15, 2014; the entire contents of which are incorporated herein by reference.

### FIELD

Embodiments described herein relate generally to an exposure method, an exposure apparatus, and method for manufacturing semiconductor device.

### BACKGROUND

An exposure method in which a fine pattern is exposed using Talbot interference is one exposure method used in lithography technology, etc. Talbot interference is a phenomenon in which reversed images and self-images of a repeating pattern formed on an exposure mask appear periodically in the travel direction of coherent light having good coherence when the light is irradiated on the exposure mask. This phenomenon is known as Talbot effect. A fine pattern is transferred by utilizing the reversed images or the self-images to expose a transfer substrate. It is desirable to stably expose the fine pattern in such lithography technology.

### BRIEF DESCRIPTION OF THE DRAWINGS

FIG. 1 is a flowchart illustrating a pattern formation method;

FIG. 2 is a schematic view illustrating the mask;

FIG. 3 is a schematic view illustrating simulation results of a light intensity distribution due to Talbot interference;

FIG. 4 is a schematic view illustrating simulation results of a light intensity distribution due to Talbot interference;

FIG. 5 is a schematic view illustrating simulation results of a light intensity distribution due to Talbot interference;

FIG. 6 is a schematic view illustrating an exposure system; and

FIG. 7A to FIG. 7D are schematic cross-sectional views illustrating the method for manufacturing the semiconductor device according to the third embodiment.

### DETAILED DESCRIPTION

According to one embodiment, an exposure method is disclosed. The method includes irradiating a first light and a second light on a mask including a plurality of light transmitting portions arranged in a periodic pattern. The first light has a peak of intensity at a first wavelength. The second light has a peak of intensity at a second wavelength. The first wavelength is shorter than a distance between the mask and a substrate disposed to be separated from the mask. The second wavelength is longer than the first wavelength. The method includes irradiating a first interference light transmitted through the light transmitting portions and a second interference light transmitted through the light transmitting portions on the substrate.

According to one embodiment, an exposure apparatus includes a light source, a stage, and a mask holder. The light source emits a first light and a second light. The first light has a peak of intensity at a first wavelength. The second light has a peak of intensity at a second wavelength. The second wavelength is longer than the first wavelength. A substrate is placed on the stage. The mask holder holds a mask at a position where a distance between the mask and the substrate is longer than the first wavelength. The mask includes a plurality of light transmitting portions disposed in a periodic pattern. A first interference light and a second interference light are irradiated on the substrate. The first interference light is transmitted through the light transmitting portions by irradiating the first light on the mask. The second interference light is transmitted through the light transmitting portions by irradiating the second light on the mask.

According to one embodiment, a method for manufacturing a semiconductor device is disclosed. The method includes irradiating a first light and a second light on a mask including a plurality of light transmitting portions disposed in a periodic pattern. The first light has a peak of intensity at a first wavelength. The second light has a peak of intensity at a second wavelength. The first wavelength is shorter than a distance between the mask and a substrate disposed to be separated from the mask. The second wavelength is longer than the first wavelength. The method includes irradiating a first interference light and a second interference light on the substrate. The first interference light is produced by the first light passing through the light transmitting portions. The second interference light is produced by the second light passing through the light transmitting portions. The method includes forming a pattern on the substrate. The pattern corresponds to a region on the substrate where the first interference light and the second interference light are irradiated.

Various embodiments will be described hereinafter with reference to the accompanying drawings.

The drawings are schematic or conceptual; and the relationships between the thicknesses and widths of portions, the proportions of sizes between portions, etc., are not necessarily the same as the actual values thereof. Further, the dimensions and/or the proportions may be illustrated differently between the drawings, even for identical portions.

In the drawings and the specification of the application, components similar to those described in regard to a drawing thereinabove are marked with like reference numerals, and a detailed description is omitted as appropriate.

### First Embodiment

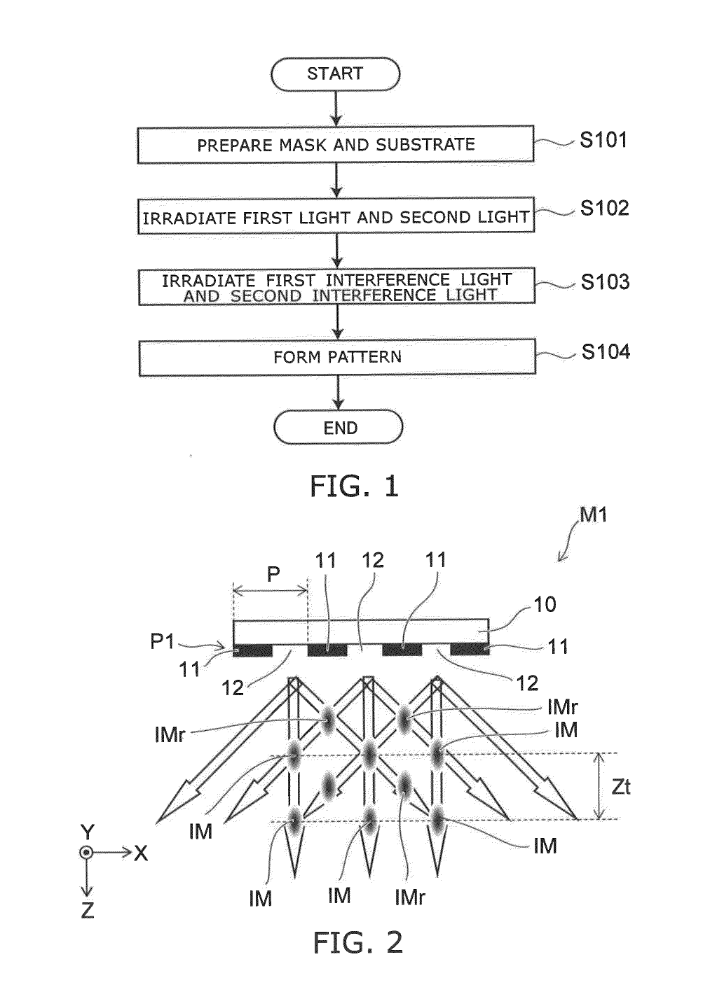

FIG. 1 is a flowchart illustrating a pattern formation method.

FIG. 1 shows a pattern formation method that uses an exposure method according to a first embodiment.

The exposure method according to the first embodiment includes irradiating a first light and a second light (step S102) and irradiating a first interference light and a second interference light (step S103). The pattern is formed in step S101 to step S104 as shown in FIG. 1.

Multiple light transmitting portions that are disposed in a periodic pattern are provided in the mask. When light is irradiated on the mask, Talbot interference that is described below occurs due to the light that passes through the mask. Lithography is performed and a pattern is formed on a substrate (a transfer substrate) by irradiating interference light occurring due to Talbot interference on the substrate.

In step S101, the substrate (the transfer substrate) and the mask that includes the multiple light transmitting portions are prepared.

FIG. 2 is a schematic view illustrating the mask. The mask M1 includes a member (a mask substrate 10) that transmits light of a prescribed wavelength, and multiple light-shielding portions 11 that are provided on the mask substrate 10. The light-shielding portions 11 shield the light that is irradiated on the mask M1 in the lithography.

The mask substrate 10 that is light-transmissive and the multiple light-shielding portions 11 form multiple light transmitting portions 12 in the mask M1. The light transmitting portions 12 correspond to portions of the mask substrate 10 where the light is not shielded by the light-shielding portions 11.

The mask substrate 10 includes, for example, quartz or synthetic quartz. The light-shielding portions 11 include, for example, chrome (Cr).

The multiple light transmitting portions 12 are provided on a plane P1 (a major surface of the mask substrate 10). One direction parallel to the plane P1 is taken as an X-axis direction. A direction perpendicular to the plane P1 is taken as a Z-axis direction. A direction that is perpendicular to the X-axis direction and perpendicular to the Z-axis direction is taken as a Y-axis direction.

The multiple light-shielding portions 11 are provided in the mask substrate 10 with a constant width and a constant spacing. Thereby, the multiple light transmitting portions 12 are disposed on the mask substrate 10 in a periodic pattern.

For example, the multiple light transmitting portions 12 are formed in a line-and-space pattern. In the example, each of the light transmitting portions 12 extends in the Y-axis direction and is arranged in the X-axis direction. The arrangement pattern of the multiple light transmitting portions 12 may be a pattern having a periodic island configuration.

The transfer substrate includes a photosensitive material (a resist) provided on the front surface. The transfer substrate is disposed to be separated from the mask M1 in the Z-axis direction. The surface of the transfer substrate (the front surface of the resist) where the interference light (the first and second interference light described below) is irradiated is disposed to be parallel to the X-Y plane (the plane P1).

In step S102, the first light L1 and the second light L2 are irradiated on the mask M1. The intensity distribution of the first light L1 has a peak (maximum value) of intensity at a first wavelength λ1. Also, the intensity distribution of the second light L2 has a peak of intensity at a second wavelength λ2 that is longer than the first wavelength λ1. Thus, in the embodiment, exposure is performed using light of different wavelengths.

The first light L1 and the second light L2 travel along the Z-axis direction. When the light that travels along the Z-axis direction is irradiated on the mask M1, Talbot interference occurs due to the transmitted light due to the light passing through the multiple light transmitting portions 12. Talbot interference will now be described.

FIG. 2 shows the Talbot interference of the mask M1. Talbot interference is the phenomenon in which reversed images IMr and self-images IM of the repeating pattern of the mask M1 appear periodically in the travel direction of the light when coherent light having good coherence is irradiated on the repeating pattern (the light-shielding portions 11 and the light transmitting portions 12) of the mask M1.

Talbot interference occurs due to at least the occurrence of zeroth order light and ±first order light from the light transmitting portions 12. Then, the self-images IM occur at the positions where all of the diffracted light has the same phase. The self-images IM refer to the imaging where a light intensity distribution corresponding to the light transmitting portions 12 appears. The reversed images IMr refer to the imaging where a light intensity distribution corresponding to the reversed pattern of the periodic pattern of the light transmitting portions 12 appears.

In the example, multiple self-images IM are arranged in the X-axis direction to correspond to the periodic pattern of the light transmitting portions 12. The positions of the reversed images IMr in the X-axis direction are between the self-images IM that are adjacent to each other in the X-axis direction.

The reversed images IMr and the self-images IM appear periodically and alternately along the Z-axis direction. The length of one period along the Z-axis direction where the self-images appear is called the Talbot distance. A pattern pitch p is the periodic pattern of the light transmitting portions 12. A wavelength λ is the wavelength of the light irradiated on the mask M1. A Talbot distance Zt is expressed by Formula (1) when the pitch p approaches the wavelength λ.

$$\begin{matrix}[ Formula 1 ] & \\ {z}_{τ} = \frac{{p}^{2}}{λ} ( 1 + \sqrt{1 - {( \frac{λ}{p} )}^{2}} ) & ( 1 )\end{matrix}$$

The Talbot distance Zt can be approximated by Formula (2) when the pitch p is not less than twice the wavelength λ.

$$\begin{matrix}[ Formula 2 ] & \\ {z}_{τ} \approx \frac{2 {p}^{2}}{λ} , p >> λ & ( 2 )\end{matrix}$$

The multiple self-images IM are arranged in the Z-axis direction at a spacing such as the Talbot distance Zt. The positions along the Z-axis direction where the reversed images IMr occur are between the self-images IM that are adjacent to each other in the Z-axis direction.

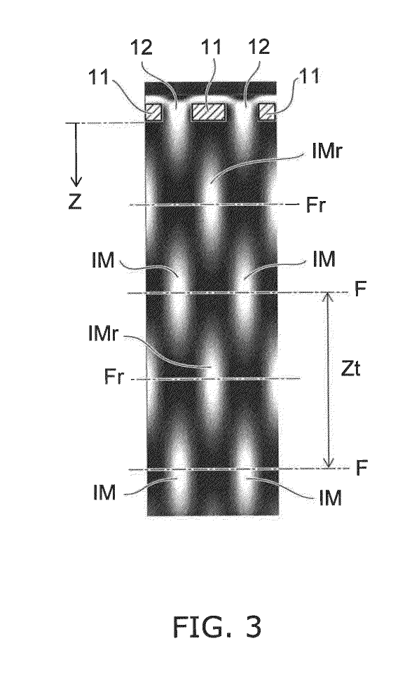

FIG. 3 shows simulation results showing the light intensity distribution due to Talbot interference.

FIG. 3 shows the light intensity distribution using a grayscale. A whiter color in the grayscale indicates a stronger light intensity. In FIG. 3, the light intensity distribution considering only the first order diffracted light is shown for convenience of description.

As shown in FIG. 3, for example, the reversed images IMr and the self-images IM appear alternately in the Z-axis direction using the lower end position of the light-shielding portions 11 as a reference. Here, a reversed image plane Fr is the plane that is parallel to the X-Y plane and includes the centers of the reversed images IMr. A self-image plane F is the plane that is parallel to the X-Y plane and includes the centers of the self-images IM. Pattern transfer can be performed at the reversed image plane Fr or the self-image plane F.

As a feature of Talbot interference, the positions of the self-images IM and the reversed images IMr in the X-Y plane do not change even when the wavelength of the light irradiated on the mask M1 is changed. However, the Talbot distance Zt changes when the wavelength of the light is changed. In other words, the imaging positions change only in the Z-axis direction when the wavelength is changed.

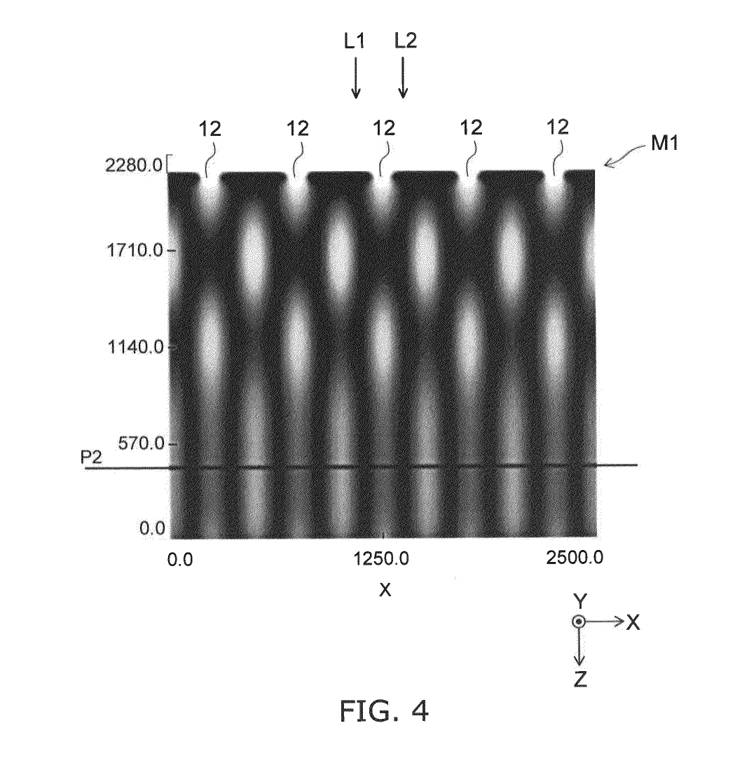

FIG. 4 shows simulation results showing a light intensity distribution due to Talbot interference. In FIG. 4 as well, similarly to FIG. 3, the light intensity distribution is shown using a grayscale. In FIG. 4, the light intensity distribution when irradiating the first light L1 on the mask M1 and the intensity distribution when irradiating the second light L2 on the mask M1 are displayed to overlap each other.

In the example, the pitch p of the light transmitting portions 12 is set to be 500 nm. The length along the X-axis direction of the light transmitting portions 12 is 100 nm. A high pressure mercury lamp is used as the light source of the first light L1 and the second light L2; the first light L1 is the i-line; and the second light L2 is the g-line.

The first interference light occurs due to the Talbot interference due to the first light L1 passing through the multiple light transmitting portions 12. The second interference light occurs due to the Talbot interference due to the second light L2 passing through the multiple light transmitting portions 12. That is, the first interference light and the second interference light are produced by the Talbot interference.

The positions in the X-Y plane of the self-images due to the first interference light are the same as the positions in the X-Y plane of the self-images due to the second interference light. The positions in the Z-axis direction of the self-images due to the first interference light are different from the positions in the Z-axis direction of the self-images due to the second interference light.

Similarly, the positions in the X-Y plane of the reversed images due to the first interference light are the same as the positions in the X-Y plane of the reversed images due to the second interference light. The positions in the Z-axis direction of the reversed images due to the first interference light are different from the positions in the Z-axis direction of the reversed images due to the second interference light.

Such a light intensity distribution of the first interference light and such a light intensity distribution of the second interference light are superimposed. At the vicinity of a plane P2 shown in FIG. 4, a portion of the self-images of the first interference light overlaps a portion of the self-images of the second interference light; and a light intensity distribution that extends in the Z-axis direction is obtained. Similarly, a portion of the reversed images of the first interference light overlaps a portion of the reversed images of the second interference light; and a light intensity distribution that extends in the Z-axis direction is obtained.

At the plane P2, the intensity is high for both the light corresponding to the self-images and the light corresponding to the reversed images. The pitch of the pattern of the light intensity distribution at the plane P2 is half of the pitch p of the light transmitting portions 12.

In step S103, such a first interference light (the first light transmitted through the light transmitting portions 12) and such a second interference light (the second light transmitted through the light transmitting portions 12) are irradiated on the transfer substrate. For example, the transfer substrate is disposed at the position of the plane P2.

The regions (the exposed regions) of the transfer substrate where the first interference light and the second interference light are irradiated have a periodicity corresponding to the periodic pattern of the light transmitting portions 12. The exposed regions include the pattern formed of the self-images of the first interference light (and the second interference light) and the pattern formed of the reversed images of the first interference light (and the second interference light). Thereby, the period of the exposed regions is 0.5 times the period (the pitch p) of the periodic pattern of the light transmitting portions 12. Thus, pattern transfer having a pitch that is half of that of the mask is possible. The period of the exposed regions where the transfer substrate is exposed is, for example, not more than 10 times the first wavelength.

When Talbot interference is utilized in lithography, at least the light passing through the mask M1 undergoes diffraction and interference; and the initial self-images are produced. Also, the transmitted light of the mask M1 produces at least first order diffracted light. The pattern pitch p (the period) of the periodic pattern of the light transmitting portions 12 being larger than the wavelength 2, of the light passing through the light transmitting portions 12 is a condition for producing such light. This condition, Formula (1), and the pitch p being set to be equal to the wavelength λ give

$$\begin{matrix}[ Formula 3 ] & \\ \begin{matrix}{z}_{τ} = \frac{{p}^{2}}{λ} ( 1 + \sqrt{1 - {( \frac{λ}{p} )}^{2}} ) \\ = λ\end{matrix} . & ( 3 )\end{matrix}$$

Accordingly, the distance between the mask M1 and the transfer substrate is set to be longer than the wavelength λ. In the case where light of different wavelengths is irradiated, the distance between the mask and the transfer substrate is set to be longer than the shorter wavelength.

In the embodiment, the first wavelength λ1 of the first light L1 is shorter than the second wavelength λ2 of the second light L2. The first wavelength λ1 is shorter than the distance between the mask M1 and the transfer substrate. Thereby, exposure using Talbot interference is possible.

In step S104, a pattern is formed on the transfer substrate. For example, the transfer substrate on which the interference light is irradiated is immersed in a developing liquid; and a portion of the resist is removed. The pattern that is formed may include a pattern that is formed in a resist and/or a pattern that is obtained by etching the foundation (a semiconductor layer, etc.) using a resist pattern as a mask.

For example, in the case where a high resolution is necessary in a lithography process when manufacturing a semiconductor device, deep ultraviolet (DUV) light from the light source of an ArF excimer laser having a wavelength of 193 nm is used as the illumination light source of the mask.

In a method of a reference example for forming a fine pattern, a mask (a reticle) that has a pattern size that is 4 times the size of the pattern that is actually formed is used; and an exposure apparatus that includes a reduction projection optical system is used.

However, as the patterns are downscaled in recent years, the formation of the mask pattern is becoming difficult even when using the mask having the pattern that is 4 times in size. Also, the formable pattern size on the wafer is approaching limits due to the physical limits of the design and the components of the optical system.

Also, an exposure method of a reference example has been proposed in which double patterning or the like is used as a resolution enhancement technique (RET) to respond to such circumstances. Double patterning is difficult due to numerous problems when solving the shift that occurs when superimposing the initial exposure and the second exposure, etc.

A pattern size L of the resolution limit pattern can be expressed by the following Formula (4), where the light source wavelength is λ and the numerical aperture of the projection optical system is NA.

$$\begin{matrix}[ Formula 4 ] & \\ L = {k}_{1} \frac{λ}{NA} & ( 4 ) \\ Here , & \\ [ Formula 5 ] & \\ NA = n sin θ . & ( 5 )\end{matrix}$$

n is the refractive index between the lens and the transfer substrate; and θ is the angle of the image point on the optical axis with respect to the radius of the exit pupil. k₁ is called the process factor. The value of k₁ to obtain the resolution for the cut-off frequency of the spatial frequency is 0.5 in the case of perpendicular incidence and 0.25 in the case of off-axis illumination.

Empirically, the upper limit of the value of sin θ for the optical design is, for example, about 0.95. Therefore, a high resolution is obtained by increasing n. However, it is difficult to set the refractive index of the medium between the optical lens and the substrate to be greater than the refractive index of the optical glass used in the lens due to the constraints of the optical design. For example, quartz is used as the optical glass for ArF. The refractive index of quartz for light of a wavelength of 193 nm is 1.56. Therefore, a medium having a refractive power that is less than 1.56 is inserted. For example, water which has a refractive index of 1.44 is used as the medium. From such a relationship, the maximum value of NA of the immersion exposure apparatus is, for example, 1.35.

In the case where an ArF excimer laser is used as the light source, the minimum resolvable dimension is 37.5 nm for k₁=0.25 and NA=1.35 in Formula (4). Also, in such a pattern transfer, even a slight error or nonuniformity of the optical system has a critical effect on the transfer precision. Therefore, there are cases where the costs of selecting the optical materials and the costs of maintaining a high degree of perfection of the optical system are enormous.

On the other hand, the resolvable pattern size is proportional to the wavelength of the light emitted from the light source. Therefore, it may be considered to further shorten the wavelength. A projection exposure apparatus is being studied in which light (extreme ultraviolet (EUV)) that has a wavelength of 13.5 nm is used.

In the case where EUV light is used, for example, NA=0.25. Also, optical systems in which NA=0.32 are being planned. When NA=0.32 and k₁=0.25, the minimum resolvable dimension when using EUV light is 10.5 nm. However, the technical degree of difficulty when using the EUV light source is high; and it is difficult to provide a light source that can provide a sufficient output for semiconductor manufacturing.

In lithography using EUV light, a reflective mask is used when transferring the semiconductor pattern. Therefore, the illumination light is incident on the mask obliquely. Therefore, contrivances for the pattern arrangement are necessary to maintain the pattern precision.

Conversely, according to a proximity method that uses the Talbot effect as in the exposure method according to the embodiment, a fine pattern that is equivalent to or finer than that of the case where the projection optical system is used can be transferred without using the projection optical system which is expensive.

By using the proximity exposure method that utilizes Talbot interference, the resolution of the pattern transfer can be increased. For example, the resolution of semiconductor lithography can be increased.

The pattern formation method according to the proximity method that uses Talbot interference has the feature that defects are not easily transferred even in the case where there are defects on the master template (the mask). This can be considered to be advantageous in the semiconductor manufacturing processes.

Thus, in the proximity exposure method that utilizes Talbot interference, a high-resolution pattern can be formed and defects can be reduced using an easy exposure method in which a projection optical system is not used.

On the other hand, for Talbot interference, the range in which one self-image IM is positioned in the Z-axis direction is finite and narrow as shown in FIG. 3 in the case where light having an intensity distribution peak at only one wavelength is used. Similarly, the range in which one reversed image IMr is positioned in the Z-axis direction is narrow. This corresponds to the depth of focus of the projection exposure. The pattern transfer must be performed by disposing the transfer substrate in such narrow ranges. Therefore, there are cases where the process is not stable.

Conversely, in the embodiment, light having peak intensities at two mutually-different wavelengths is used. By performing the exposure at the different wavelengths as shown in FIG. 4, it is possible to enlarge the region of the imaging in the Z-axis direction; and the depth of focus can be increased. The range in the Z-axis direction having a high light intensity is wide. Thereby, the exposure can be performed stably. Also, as described above, the pitch of the pattern that is transferred can be set to be half of the pitch of the mask pattern.

The resolution limit of a proximity exposure apparatus of a reference example using DUV light is, for example, about 4 μm to 5 μm. For example, the resolution limit of the exposure apparatus is dependent on the wavelength of the exposure and the gap length (the distance between the mask and the transfer substrate). Although the resolution increases as the gap length is reduced, the lower limit of the gap length is limited due to the stability of the process. Therefore, in the proximity apparatus of the reference example, it is difficult to form a pattern having a width that is not more than 10 times the wavelength. The wavelength of the i-line which is one spectrum of the DUV light source is 356 nm; and 10 times 356 nm is 3.56 μm. In the exposure apparatus of the reference example, it is difficult to form a pattern having a width that is 1.8 μm which is half of 10 times the wavelength of the i-line.

Conversely, according to the embodiment, a pattern having a pitch that is less than 10 times the wavelength can be formed by using Talbot lithography.

In the example described above, the first light L1 includes the i-line; and the second light L2 includes the g-line. In the embodiment, the first light L1 may include at least one selected from the i-line, the g-line, and the h-line.

Although the first light L1 and the second light L2 are used in the embodiment, light of three or more different wavelengths may be used. Here, light of different wavelengths is light for which the wavelengths at the centers of the spectra are different, e.g., light for which the wavelengths where the intensity distributions of the light have peaks are different.

For example, a third light L3 is irradiated on the mask in addition to the first light L1 and the second light L2. The intensity distribution of the third light L3 has a peak of intensity at a third wavelength k3. Here, the third wavelength λ3 is different from the first wavelength λ1 and different from the second wavelength λ2. The third wavelength λ3 is longer than the first wavelength λ1.

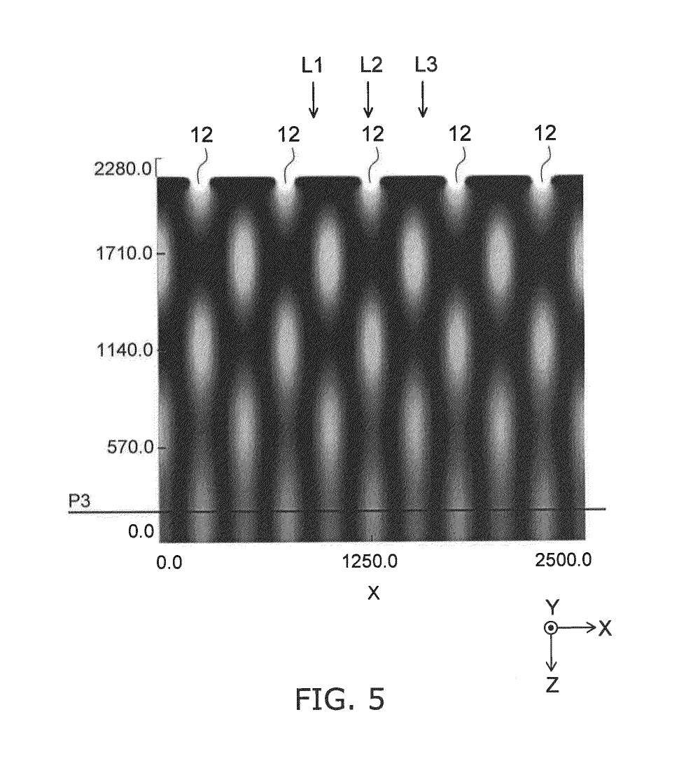

FIG. 5 is a schematic view illustrating simulation results of a light intensity distribution due to Talbot interference. In FIG. 5 as well, similarly to FIG. 4, the light intensity distribution is illustrated using a grayscale. In FIG. 5, the intensity distributions of the first light L1, the second light L2, and the third light L3 when irradiated on the mask M1 are displayed to overlap each other.

Similarly to the example shown in FIG. 4, the pitch p of the light transmitting portions 12 is 500 nm; and the width of the light transmitting portions 12 is 100 nm. In the example, the first light L1 is the i-line; the second light L2 is the h-line; and the third light L3 is the g-line.

The first to third interference light occurs due to Talbot interference due to the first to third light L1 to L3 passing through the multiple light transmitting portions 12.

The positions in the X-Y plane of the self-images are the same for each of the first to third interference light. The positions in the Z-axis direction of the self-images are different from each other for each of the first to third interference light.

The positions in the X-Y plane of the reversed images are the same for each of the first to third interference light. The positions in the Z-axis direction of the reversed images are different from each other for each of the first to third interference light.

A light intensity distribution that extends in the Z-axis direction is obtained by superimposing the first to third interference light that have such light intensity distributions. For example, the intensity is high for both the light corresponding to the self-images and the light corresponding to the reversed images at a plane P3 shown in FIG. 5. A pattern having a period that is half of the pitch p of the mask M1 can be exposed by disposing the transfer substrate at the position of the plane P3.

In the embodiment as described above, light of three or more different wavelengths may be used. Any combination of wavelengths may be used.

The light source of the first light L1 and the second light L2 may be an ArF excimer laser or a KrF excimer laser. Different types of light sources such as an excimer laser, a high pressure mercury lamp, etc., may be used in combination as the light source.

The first light L1 and the second light L2 may be irradiated on the mask separately at different times.

The first light L1 and the second light L2 may be irradiated on the mask simultaneously. In such a case, the light that is irradiated on the mask can be considered to be one light in which the first light L1 and the second light L2 are superimposed. In other words, the embodiment includes the case where light having intensity distribution peaks at multiple mutually-different wavelengths is irradiated.

In the embodiment, the ratio of the intensity of the second light L2 and the intensity of the first light L1 is modifiable. For example, the ratio can be modified by providing an optical filter between the light source and the transfer substrate. The ratio of the irradiation time (the length of the time of the irradiation) of the second light L2 and the irradiation time of the first light L1 may be modified.

For example, the intensity of the first light L1 and the intensity of the second light L2 are adjusted independently. Thereby, the intensity of the interference light of the self-images IM and the intensity of the interference light of the reversed images IMr can be adjusted. Also, the width in the X-Y plane of the self-images IM and the width in the X-Y plane of the reversed images IMr can be adjusted. The contrast of the exposure pattern can be increased for the surface of the transfer substrate where the light is irradiated. According to the embodiment, a fine pattern can be exposed stably.

### Second Embodiment

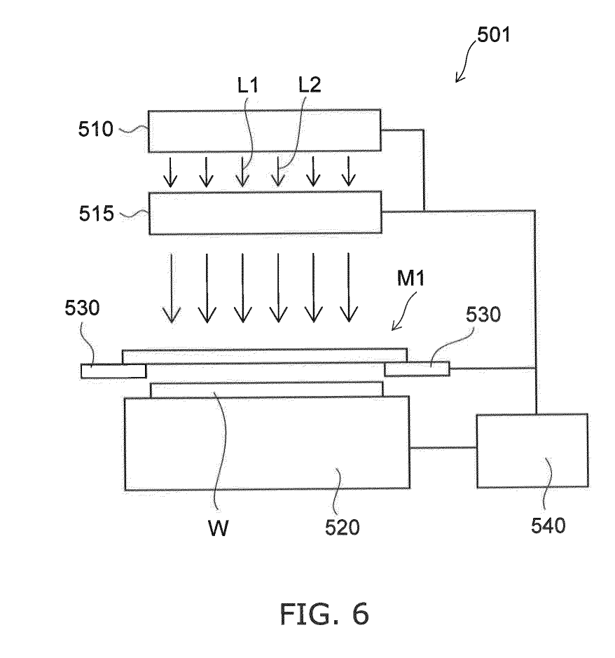

FIG. 6 is a schematic view illustrating an exposure system.

The exposure system shown in FIG. 6 includes an exposure apparatus 501 and a controller 540 according to a second embodiment.

The exposure apparatus 501 includes a light source 510, a stage 520, and a mask holder 530. The exposure apparatus 501 is, for example, a proximity exposure apparatus. The exposure apparatus 501 implements exposure by the exposure method described in the first embodiment. The controller 540 may be considered to be a portion of the exposure apparatus 501.

The light source 510 emits the light to be used in the exposure. The light source 510 emits light that includes the first light L1 and the second light L2. Further, a light controller 515 is provided between the light source 510 and the stage 520 in the optical path of the first light L1 or the second light L2.

The light controller 515 separates the light emitted from the light source 510. The light controller 515 includes, for example, an optical filter that transmits light of a prescribed wavelength. Thereby, light of the desired wavelength can be obtained. Also, the ratio of the intensity of the second light L2 and the intensity of the first light L1 can be adjusted.

For example, in the case where the light source 510 includes a high pressure mercury lamp, the light controller 515 includes an optical filter that transmits the g-line and an optical filter that transmits the i-line. Light of the desired wavelength can be obtained by switching such filters.

The light controller 515 may include an optical system that guides the light emitted from the light source 510 toward the stage 520. The light controller 515 may include a mechanism such as an aperture, etc., that aligns the travel direction of the light. Thereby, the resolution can be increased.

The light source 510 may include a portion that emits light including the first light L1 and a portion that emits light including the second light L2.

A transfer substrate is placed on the stage 520. In the example shown in FIG. 6, a transfer substrate W is placed on the stage 520. For example, the stage 520 suction-holds the transfer substrate W on the stage 520 by vacuum-attachment. The stage 520 is provided to be movable along the front surface of the transfer substrate W along, for example, two axes (the X-axis and the Y-axis). The relative positional relationship between the transfer substrate W and an exposure mask held by the mask holder 530 described below is changed by moving the stage 520.

The mask holder 530 holds the mask M1 in which the multiple light transmitting portions 12 are provided. The mask holder 530 may be provided to be movable.

The controller 540 controls the light source 510, the light controller 515, the stage 520, and the mask holder 530. The controller 540 controls the timing and the light amount of the emission of the light by the light source 510, the wavelength of the light irradiated from the light controller 515 toward the transfer substrate W, the timing and amount of movement of the stage 520, etc. The controller 540 controls the holding and release of the mask M1 by the mask holder 530 and, if necessary, operations such as movement, etc. Also, the controller 540 controls the distance between the mask M1 and the transfer substrate W according to the pitch p of the periodic pattern of the mask M1.

To perform the exposure by the exposure apparatus 501, the transfer substrate W is placed on the stage 520; and the mask holder 530 holds the mask M1. The alignment between the transfer substrate W and the mask M1 is performed by moving at least one selected from the stage 520 and the mask holder 530.

Then, the light is emitted from the light source 510. The light that is emitted from the light source 510 passes through the light controller 515. Thereby, the first light L1 and the second light L2 are irradiated on the mask M1. The first light L1 and the second light L2 become interference light due to Talbot interference due to the mask M1.

The interference light is irradiated on the transfer substrate W that is on the stage 520. The resist that is provided on the transfer substrate W is exposed by the interference light irradiated on the transfer substrate W. Thus, in the exposure apparatus 501, the exposure method according to the embodiment is implemented; and exposure of a fine pattern can be performed stably.

### Third Embodiment

The embodiment relates to a method for manufacturing a semiconductor device. The pattern formation method described in the first embodiment is used in the method for manufacturing the semiconductor device according to the embodiment.

The semiconductor device includes a semiconductor element such as a transistor, a diode, a resistor, a condenser, etc. The semiconductor device is an integrated circuit (LSI), a semiconductor memory device (e.g., flash memory), a semiconductor light emitting element (e.g., an LED), a solid-state imaging element (e.g., a CMOS image sensor), etc. However, in the embodiment, the semiconductor device is not limited thereto. The pattern formation method according to the embodiment may be used for an electronic device such as a display, etc.

The semiconductor device is manufactured by repeating multiple processes such as a process of forming a pattern on a substrate, an inspection process of the pattern, a cleaning process, a heat treatment process, an impurity introduction process, a diffusion process, a planarizing process, etc.

The processes of forming the pattern on the substrate include film formation, resist coating, exposure, developing, etching, resist removal, etc. These processes may include the pattern formation method described above. The pattern that is formed in the substrate is, for example, an interconnect pattern or an impurity implantation pattern.

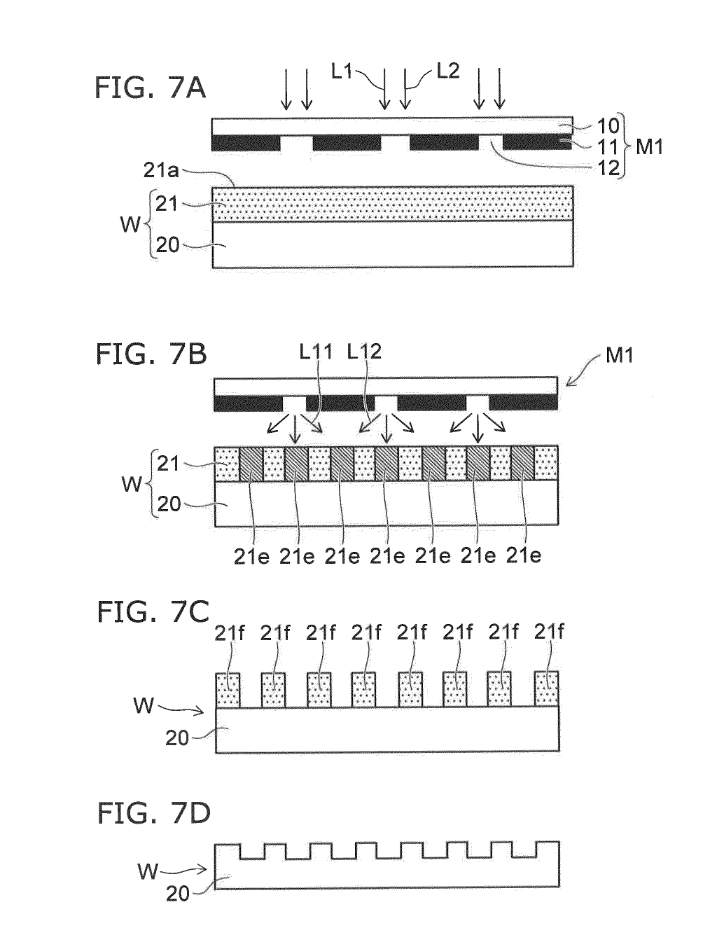

FIG. 7A to FIG. 7D are schematic cross-sectional views illustrating the method for manufacturing the semiconductor device according to the third embodiment.

As shown in FIG. 7A, the transfer substrate W that includes a photosensitive material (a resist 21) coated onto a wafer 20 is prepared. The wafer 20 is, for example, a semiconductor substrate of Si, etc. A semiconductor layer, an insulating layer, a conductive layer, etc., may be provided on the semiconductor substrate.

The mask M1 is disposed to oppose a front surface 21a of the resist 21 (the major surface of the substrate W). The mask M1 includes the multiple light transmitting portions 12 disposed in a periodic pattern. The mask M1 is disposed so that the multiple light transmitting portions 12 are arranged on the plane parallel to the front surface 21a. Then, the first light L1 and the second light L2 are irradiated on the mask M1. As described above, the first light L1 has a peak of intensity at the first wavelength λ1; and the second light L2 has a peak of intensity at the second wavelength λ2. The second wavelength X2 is longer than the first wavelength λ1. Also, the distance along the Z-axis direction between the mask M1 and the transfer substrate W is longer than the first wavelength λ1 of the first light L1.

As shown in FIG. 7B, Talbot interference occurs due to the irradiated first light L1 passing through the mask M1. Thereby, a first interference light L11 occurs. Also, Talbot interference occurs due to the irradiated second light L2 passing through the mask M1. Thereby, a second interference light L12 occurs.

The first interference light L11 and the second interference light L12 are irradiated on portions (regions 21e) of the resist 21 of the transfer substrate W. The regions 21e have periodicity corresponding to the periodic pattern of the mask M1. For example, the period of the regions 21e is 0.5 times the period of the periodic pattern of the mask M1. Thus, a fine pattern can be exposed.

Subsequently, the resist 21 is immersed in a developing liquid. Thereby, a pattern is formed in the resist 21 of the transfer substrate W. In the case where the resist 21 is a positive type as shown in FIG. 7C, the regions 21e described above are removed; and other portions (regions 21f) of the resist 21 remain on the transfer substrate W. The regions 21f have a pattern corresponding to the regions 21e where the first interference light L11 and the second interference light L12 are irradiated.

As shown in FIG. 7D, the wafer 20 is etched using the resist 21 (the regions 21f) as a mask. Thereby, a pattern that corresponds to the periodic pattern of the mask M1 is formed on the wafer 20. Subsequently, the resist 21 is removed. Etching may not be performed; for example, an impurity may be implanted using the resist 21 as a mask; and the resist 21 may be removed subsequently.

The semiconductor device is manufactured by performing multiple processes including the pattern formation process described above as necessary. According to the embodiment, a semiconductor device that includes a fine pattern can be manufactured stably.

According to the embodiments, an exposure method, an exposure apparatus, and a method for manufacturing a semiconductor device can be provided in which a fine pattern can be exposed stably.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

Hereinabove, embodiments of the invention are described with reference to specific examples. However, the embodiment of the invention is not limited to these specific examples. For example, one skilled in the art may similarly practice the invention by appropriately selecting specific configurations of components such as the mask, the transfer substrate, the light source, the stage, etc., from known art; and such practice is within the scope of the invention to the extent that similar effects can be obtained.

Further, any two or more components of the specific examples may be combined within the extent of technical feasibility and are included in the scope of the invention to the extent that the purport of the invention is included.

Moreover, all exposure methods, exposure apparatuses, and methods for manufacturing semiconductor device practicable by an appropriate design modification by one skilled in the art based on the exposure methods, the exposure apparatuses, and methods for manufacturing semiconductor device described above as embodiments of the invention also are within the scope of the invention to the extent that the spirit of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. An exposure method, comprising:
irradiating a first light and a second light on a mask including a plurality of light transmitting portions arranged in a periodic pattern, the first light having a peak of intensity at a first wavelength, the second light having a peak of intensity at a second wavelength, the first wavelength being shorter than a distance between the mask and a substrate disposed to be separated from the mask, the second wavelength being longer than the first wavelength; and
irradiating a first interference light transmitted through the light transmitting portions and a second interference light transmitted through the light transmitting portions on the substrate.

2. The method according to claim 1, wherein
a region where the first interference light and the second interference light are irradiated on the substrate has periodicity corresponding to the periodic pattern, and
the period of the region is not more than 10 times the first wavelength.

3. The method according to claim 2, wherein the first interference light and the second interference light are produced by Talbot interference.

4. The method according to claim 3, wherein the region includes a pattern formed of a self-image of the first interference light and a pattern formed of a reversed image of the first interference light.

5. The method according to claim 1, wherein the ratio of an intensity of the first light and an intensity of the second light is modifiable.

6. The method according to claim 1, wherein the plurality of light transmitting portions is provided on a plane parallel to a surface of the substrate where the first interference light is irradiated.

7. The method according to claim 6, wherein each of the plurality of light transmitting portions extends in a first direction in the plane and is arranged in a second direction in the plane, the second direction intersecting the first direction.

8. The method according to claim 1, wherein a light source of the first light includes at least one selected from an ArF excimer laser and a KrF excimer laser.

9. The method according to claim 1, wherein
a light source of the first light is a mercury lamp, and
the first light includes at least one selected from an i-line, a g-line, and a h-line.

10. The method according to claim 1, further including:
irradiating a third light on the mask, the third light having a peak of intensity at a third wavelength longer than the first wavelength; and
irradiating a third interference light on the substrate, the third interference light being produced by the third light passing through the light transmitting portions.

11. An exposure apparatus, comprising:
a light source emitting
a first light having a peak of intensity at a first wavelength, and
a second light having a peak of intensity at a second wavelength, the second wavelength being longer than the first wavelength;
a stage, a substrate being placed on the stage; and
a mask holder holding a mask at a position where a distance between the mask and the substrate is longer than the first wavelength, the mask including a plurality of light transmitting portions disposed in a periodic pattern,
a first interference light and a second interference light being irradiated on the substrate, the first interference light being transmitted through the light transmitting portions by irradiating the first light on the mask, the second interference light being transmitted through the light transmitting portions by irradiating the second light on the mask.

12. The apparatus according to claim 11, wherein
a region of the substrate where the first interference light and the second interference light are irradiated has periodicity corresponding to the periodic pattern, and
the period of the region is not more than 10 times the first wavelength.

13. The apparatus according to claim 12, wherein the first interference light and the second interference light are produced by Talbot interference.

14. The apparatus according to claim 13, wherein the region includes a pattern formed of a self-image of the first interference light and a pattern formed of a reversed image of the first interference light.

15. The apparatus according to claim 11, wherein the ratio of an intensity of the first light and an intensity of the second light is modifiable.

16. The apparatus according to claim 11, wherein the plurality of light transmitting portions is provided on a plane parallel to a surface of the substrate where the first interference light is irradiated.

17. The apparatus according to claim 11, wherein the light source includes at least one selected from an ArF excimer laser and a KrF excimer laser.

18. The apparatus according to claim 11, wherein
the light source is a mercury lamp, and
the first light includes at least one selected from an i-line, a g-line, and a h-line.

19. The apparatus according to claim 11, wherein
the light source also emits a third light having a peak of intensity at a third wavelength, the third wavelength being longer than the first wavelength, and
a third interference light also is irradiated on the substrate by irradiating the third light on the mask, the third interference light being produced by the third light passing through the light transmitting portions.

20. A method for manufacturing a semiconductor device, comprising:
irradiating a first light and a second light on a mask including a plurality of light transmitting portions disposed in a periodic pattern, the first light having a peak of intensity at a first wavelength, the second light having a peak of intensity at a second wavelength, the first wavelength being shorter than a distance between the mask and a substrate disposed to be separated from the mask, the second wavelength being longer than the first wavelength;
irradiating a first interference light and a second interference light on the substrate, the first interference light being produced by the first light passing through the light transmitting portions, the second interference light being produced by the second light passing through the light transmitting portions; and
forming a pattern on the substrate, the pattern corresponding to a region on the substrate where the first interference light and the second interference light are irradiated.
